(19) United States
(12) Patent Application Publication
(10) Pub. No.: US 2026/0171822 A1
(43) Pub. Date: Jun. 18, 2026

(54) Charging Protection Method and User Equipment

(71) Applicant: MEDIATEK INC., Hsinchu City (TW)

(72) Inventors: Yi-Lin Huang, Hsinchu City (TW); Jia-You Chuang, Hsinchu City (TW); Kai-Sheng Wang, Hsinchu City (TW); Sheng-Xuan You, Hsinchu City (TW); Cheng-Hsiung Huang, Hsinchu City (TW); En-Ming Chang, Hsinchu City (TW)

(73) Assignee: MEDIATEK INC., Hsinchu City (TW)

(21) Appl. No.: 18/979,628

(22) Filed: Dec. 13, 2024

(51) Int. Cl. H02J 7/00; G01R 19/165; G08B 21/18

(52) U.S. Cl. CPC H02J 7/64; G01R 19/16542; G08B 21/182; G08B 21/185; H02J 2207/30

(57) ABSTRACT

A charging protection method, for a user equipment being charged by a power supply through a charging port, includes comparing, by a voltage comparator of the user equipment, voltages of pins of the charging port with a first threshold and generating a comparison result; and determining whether to keep charging the user equipment according to the comparison result.

### BACKGROUND

Recently, many mobile phones on the market no longer come with chargers, so users need to purchase one of chargers. However, the quality of available chargers varies, which may cause damage to the mobile phone. For example, the signal pins in the universal serial bus (USB) port of the charger may short-circuit with the supply voltage pin, causing the voltage of the signal pins to be too high when charging the mobile phone. Therefore, it has become a goal of the industry to prevent mobile phones from being damaged due to high voltage of the signal pins while being charged.

### SUMMARY

Therefore, the purpose of the present invention is to provide a charging protection method and related user equipment to prevent the mobile phone from being damaged due to high voltage while being charged.

The embodiment of the present invention discloses a charging protection method, for a user equipment being charged by a power supply through a charging port, comprising comparing, by a voltage comparator of the user equipment, voltages of pins of the charging port with a first threshold and generating a comparison result; and determining whether to keep charging the user equipment according to the comparison result.

The embodiment of the present invention discloses a user equipment, comprising a charging module, configured to receive power from a power supply through a charging port; a voltage comparator, configured to compare voltages of pins of the charging port with a first threshold when the power supply connects and provides power to the charging port, and to accordingly generate a comparison result; and a decision module, configured to determine whether to keep charging the user equipment according to the comparison result.

The embodiment of the present invention discloses a charging system, comprising a power supply; and a user equipment, coupled to the power supply, comprising: a charging module, configured to receive power from the power supply through a charging port; a voltage comparator, configured to compare voltages of pins of the charging port with a first threshold when the power supply connects and provides power to the charging port, and to accordingly generate a comparison result; and a decision module, configured to determine whether to keep charging the user equipment according to the comparison result.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a schematic diagram of a charging protection system according to an embodiment of the present invention.

FIG. 2 is a schematic diagram of a charging protection system according to another embodiment of the present invention.

FIG. 3 is a flowchart of the charging protection method according to an embodiment of the present invention.

### DETAILED DESCRIPTION

Certain terms are used throughout the description and following claims to refer to particular components. As one skilled in the art will appreciate, hardware manufacturers may refer to a component by different names. This document does not intend to distinguish between components that differ in name but not function. In the following description and in the claims, the terms “include” and “comprise” are utilized in an open-ended fashion, and thus should be interpreted to mean “include, but not limited to”. “Approximately” means that within the acceptable error range, a person with ordinary knowledge in the field can solve the technical problem within a certain error range and basically achieve the technical effect. Also, the term “couple” is intended to mean either an indirect or direct, wired or wireless electrical connection.

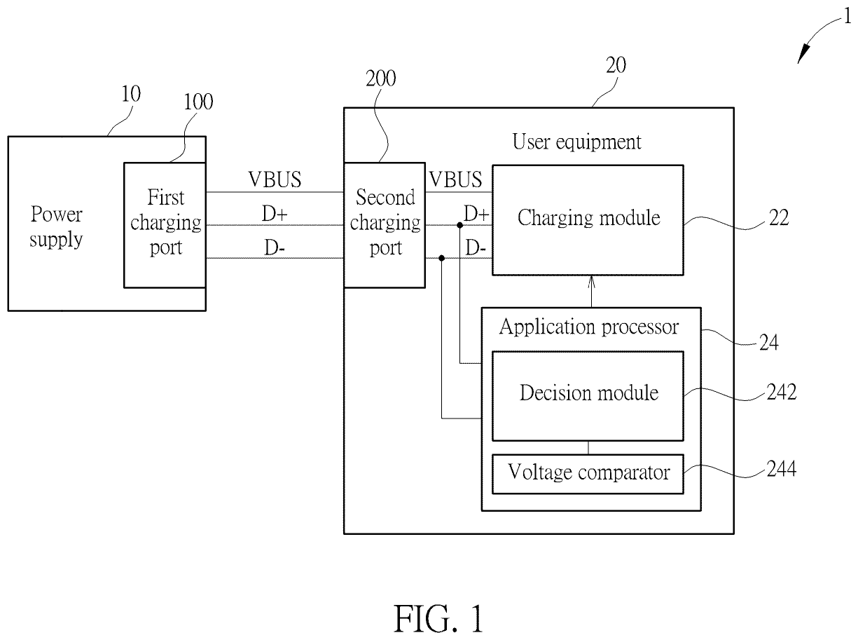

Please refer to FIG. 1. FIG. 1 is a schematic diagram of a charging system 1 according to an embodiment of the present invention. The charging system 1 includes a power supply 10 having a first charging port 100 and a user equipment 20 having a second charging port 200. The power supply 10 may be electrically connected to the user equipment 20 through the first charging port 100 and the second charging port 200, so as to charge the user equipment 20. The user equipment 20 includes a charging module 22 and an application processor 24, which are coupled to each other. When the charging module 22 receives power from the power supply 10, that is, the user equipment 20 is charged by the power supply 10, the application processor 24 may determine whether the user equipment 20 may be damaged and determine whether to keep charging the user equipment 20 (e.g. receiving power from the power supply 10) accordingly.

Specifically, the application processor 24 includes a decision module 242 and a voltage comparator 244. The voltage comparator 244 may compare voltages of signal pins D+ and D− of the second charging port 200 with a first threshold when the power supply 10 connects and provides power to the user equipment 20, and accordingly generate a comparison result. The decision module 242 may determine whether to keep charging the user equipment 20 according to the comparison result. It should be noted that, the first charging port 100 and the second charging port 200 may conform to specifications of universal serial bus (USB) standard-A, standard-B and type-C, but not limited thereto. For example, as shown in FIG. 1, if the first charging port 100 and the second charging port 200 conform to specification of USB standard-A, both of them include a power pin VBUS, differential signal pins D+/D− and a ground pin GND (not shown in FIG. 1).

For the sake of brevity, the following embodiments are described in a scenario where the user equipment 20 is charged. In order to prevent the user equipment 20 from being damaged by high voltage, in an event that the comparison result indicates that at least one of the voltages of signal pins D+ and D− is not lower than the first threshold, the charging module 22 is disabled, such that the user equipment 20 is not charged. On the other hand, in an event that the comparison result indicates that the voltages of the signal pins D+ and D− are lower than the first threshold, the charging module 22 may keep receiving power from the power supply 10, such that the user equipment keeps being charged. In an example, a normal voltage of the signal pins is 3.3 Volts (V), and the first threshold may be set to 3.8 V accordingly. When the at least one of the voltages of the signal pins D+ and D− is higher than 3.8 V, the charging module 22 is disabled and the user equipment 20 stops receiving power from the power supply 10 to avoid damage.

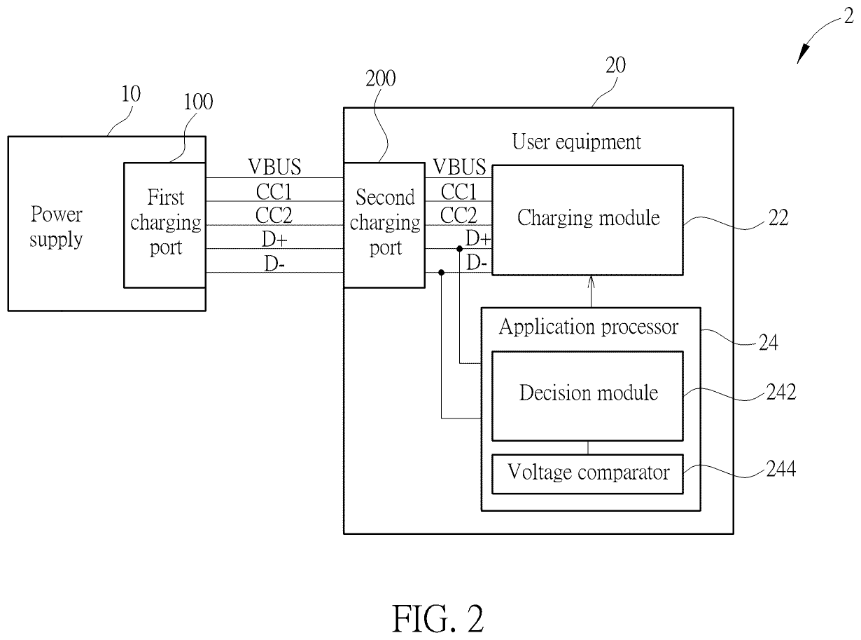

In an embodiment, the first charging port 100 and the second charging port 200 conform to specifications of universal serial bus (USB) type-C. Please refer to FIG. 2. FIG. 2 is a schematic diagram of a charging system 2 according to an embodiment of the present invention. The charging system 2 is derived from the charging system 1, so the same components are denoted by the same symbols. The difference between the charging system 2 and the charging system 1 is that the first charging port 100 and the second charging port 200 of the charging system 2 conform to specifications of universal serial bus (USB) type-C, and further include a first specific pin CC1 and a second specific pin CC2. The application processor 24 may send the comparison result to the power supply 10 through the specific pin CC1 or the specific pin CC2. In this way, the power supply 10 may determine whether to keep providing power to the user equipment 20 according to the comparison result sent from the application processor 24. For example, when the at least one of the voltages of signal pins D+ and D− is higher than 3.8 V, the power supply 10 is disabled and stops providing power to the user equipment 20 according to the comparison result, so as to prevent the user equipment 20 from being damaged due to high voltage.

It should be noted that the first charging port 100 and the second charging port 200 of the charging system 2 further include super-speed differential signal pins SSRXn2 and SSRXp2, an auxiliary pin SBU1 (not shown in FIG. 2), etc. The application processor 24 may determine whether voltages of the super-speed differential signal pins SSRXn2 and SSRXp2 and the auxiliary pin SBU1 are lower than various thresholds and determine whether to keep charging the user equipment 20 accordingly.

In another embodiment, the application processor 24 of the charging system 1 or the charging system 2 may further trigger an alarm message when the at least one of the voltages of signal pins D+ and D− is higher than the first threshold. The alarm message may be presented in the form of a sound or a text on a display screen of the user equipment 20 to remind users to remove the connection between the power supply 10 and the user equipment 20, but not limited thereto.

It should be noted that the charging systems 1-2 are different embodiments of the present invention, those skilled in the art may make different modifications accordingly, and are not limited thereto. For example, for the first charging port and the second charging port conformed to specifications of universal serial bus (USB) type-C, in an event that the comparison result indicates that at least one of the voltages of signal pins D+ and D− is not lower than the first threshold, the user equipment may simultaneously stop receiving power from the power supply, trigger the alarm message to remind users, and send the comparison result to the power supply to indicate the power supply to stop providing power to the user equipment. In another example, the decision module 242 may determine which USB specification the charging ports of the user equipment and the power supply are conformed. In an event that the comparison result indicates that at least one of the voltages of signal pins D+ and D− is not lower than the first threshold, the user equipment may accordingly stop receiving power from the power supply, trigger the alarm message to remind users, or send the comparison result to the power supply to indicate the power supply to stop providing power to the user equipment.

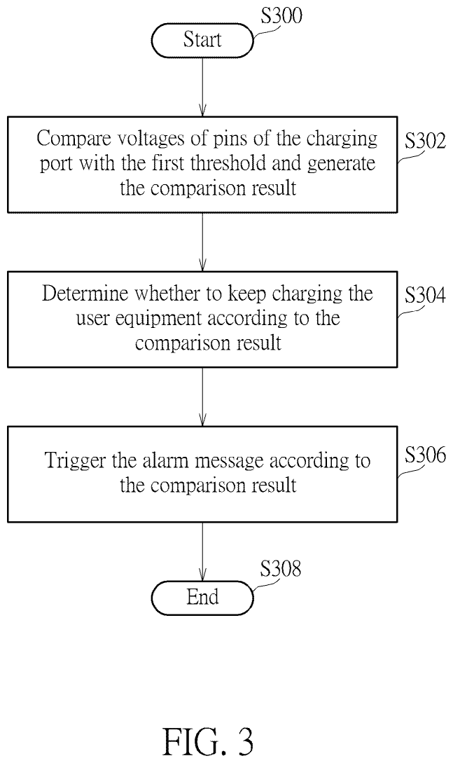

Finally, the charging protection method of the charging system 1 or the charging system 2 may be summarized as a process 3, as shown in FIG. 3. The process 3 includes the following steps:
Step S300: Start.
Step S302: Compare voltages of pins of the charging port with the first threshold and generate the comparison result.
Step S304: Determine whether to keep charging the user equipment according to the comparison result.
Step S306: Trigger the alarm message according to the comparison result.
Step S308: End.

The detailed description of the process 3 is as described above, and will not be repeated here.

It should be noted that the abovementioned description, steps, procedures and/or processes including suggested steps can be realized by means that could be hardware, software, firmware (known as a combination of a hardware device and computer instructions and data that reside as read-only software on the hardware device), an electronic system, or combination thereof. Examples of hardware can include analog, digital and mixed circuits known as microcircuit, microchip, or silicon chip. Examples of the charging system 1 and the charging system 2 may include a system on chip (SoC), system in package (SiP), a computer on module (CoM) and the computer system. Any of the abovementioned procedures and examples above may be compiled into program codes or instructions that are stored in a storage unit. The storage device may include read-only memory (ROM), flash memory, random access memory (RAM), subscriber identity module (SIM), hard disk, or CD-ROM/DVD-ROM/BD-ROM, but not limited thereto. The application processor 24 may read and execute the program codes or the instructions stored in the storage device for realizing the abovementioned functions.

Furthermore, the voltage comparator 244 may be implemented by any existing voltage comparator or operational amplifier (op-amp) on the SoC, SiP, CoM or the computer system of the charging system. Compared with the prior art that requires additional circuits or devices to detect charging problems, the present invention may reduce costs. For example, utilize existing devices, such as a comparator integrated circuit (IC) (e.g. LM339 or LM324), an opt-coupler, or relays and a resistor network, as the voltage comparator of the present invention, those skilled in the art may make different modifications accordingly, and are not limited thereto.

In addition, the scenario that the voltages of the signal pins exceed the threshold may be caused by a short circuit between the power pin and the signal pins, or by an environment with excessive moisture, but not limited thereto.

In summary, the present invention may determine whether to keep charging the user equipment according to whether the voltages of the pins of the charging port are too high. In this way, the user equipment of the present invention may prevent from being damaged due to high voltage.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A charging protection method, for a user equipment being charged by a power supply through a charging port, comprising:
comparing, by a voltage comparator of the user equipment, voltages of pins of the charging port with a first threshold and generating a comparison result; and
determining whether to keep charging the user equipment according to the comparison result.

2. The charging protection method of claim 1, wherein the step of determining whether to keep charging the user equipment according to the comparison result comprises:
keeping charging the user equipment through a charging module of the user equipment by the power supply in an event that the comparison result indicates that the voltages are lower than the first threshold; and
disabling the charging module and not charging the user equipment in an event that the comparison result indicates that at least one of the voltages is not lower than the first threshold.

3. The charging protection method of claim 2, wherein the step of determining whether to keep charging the user equipment according to the comparison result further comprises:
triggering an alarm message in the event that the comparison result indicates that at least one of the voltages is not lower than the first threshold.

4. The charging protection method of claim 1, wherein the charging port and the power supply conform to specifications of universal serial bus (USB) type C.

5. The charging protection method of claim 4, wherein the step of determining whether to keep charging the user equipment according to the comparison result comprises:
sending the comparison result to the power supply;
keeping charging the user equipment through a charging module of the user equipment by the power supply in an event that the comparison result indicates that the voltages are lower than the first threshold; and
disabling the power supply and not charging the user equipment in an event that the comparison result indicates that at least one of the voltages is not lower than the first threshold.

6. The charging protection method of claim 5, wherein the step of determining whether to keep charging the user equipment according to the comparison result further comprises:
triggering an alarm message in the event that the comparison result indicates that at least one of the voltages is not lower than the first threshold.

7. A user equipment, comprising:
a charging module, configured to receive power from a power supply through a charging port;
a voltage comparator, configured to compare voltages of pins of the charging port with a first threshold when the power supply connects and provides power to the charging port, and to accordingly generate a comparison result; and
a decision module, configured to determine whether to keep charging the user equipment according to the comparison result.

8. The user equipment of claim 7, wherein the charging module keeps receiving power from the power supply and the user equipment keeps being charged in an event that the comparison result indicates that the voltages are lower than the first threshold; and the charging module is disabled and the user equipment is not charged in an event that the comparison result indicates that at least one of the voltages is not lower than the first threshold.

9. The user equipment of claim 8, wherein the decision module further triggers an alarm message in an event that the comparison result indicates that at least one of the voltages is not lower than the first threshold.

10. The user equipment of claim 7, wherein the charging port and the power supply conform to specifications of universal serial bus (USB) type C.

11. The user equipment of claim 10, wherein the user equipment sends the comparison result to the power supply, the charging module keeps receiving power from the power supply and the user equipment keeps being charged in an event that the comparison result indicates that the voltages are lower than the first threshold; and the power supply is disabled and the user equipment is not charged in an event that the comparison result indicates that at least one of the voltages is not lower than the first threshold.

12. The user equipment of claim 11, wherein the decision module further triggers an alarm message in an event that the comparison result indicates that at least one of the voltages is not lower than the first threshold.

13. A charging system, comprising:
a power supply; and
a user equipment, coupled to the power supply, comprising:
a charging module, configured to receive power from the power supply through a charging port;
a voltage comparator, configured to compare voltages of pins of the charging port with a first threshold when the power supply connects and provides power to the charging port, and to accordingly generate a comparison result; and
a decision module, configured to determine whether to keep charging the user equipment according to the comparison result.

14. The charging system of claim 13, wherein the charging module keeps receiving power from the power supply and the user equipment keeps being charged in an event that the comparison result indicates that the voltages are lower than the first threshold; and the charging module is disabled and the user equipment is not charged in an event that the comparison result indicates that at least one of the voltages is not lower than the first threshold.

15. The charging system of claim 14, wherein the decision module further triggers an alarm message in an event that the comparison result indicates that at least one of the voltages is not lower than the first threshold.

16. The charging system of claim 13, wherein the charging port and the power supply conform to specifications of universal serial bus (USB) type C.

17. The charging system of claim 16, wherein the user equipment sends the comparison result to the power supply, the charging module keeps receiving power from the power supply and the user equipment keeps being charged in an event that the comparison result indicates that the voltages are lower than the first threshold; and the power supply is disabled and the user equipment is not charged in an event that the comparison result indicates that at least one of the voltages is not lower than the first threshold.

18. The charging system of claim 17, wherein the decision module further triggers an alarm message in an event that the comparison result indicates that at least one of the voltages is not lower than the first threshold.
